(19) United States
(12) Patent Application Publication
(10) Pub. No.: US 2023/0121332 A1
(43) Pub. Date: Apr. 20, 2023

(54) RADIO FREQUENCY DEVICES, SILICON CARBIDE HOMOEPITAXIAL SUBSTRATES AND MANUFACTURING METHODS THEREOF

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 17/967,933

(22) Filed: Oct. 18, 2022

(30) Foreign Application Priority Data
Oct. 20, 2021 (CN) 202111222935.0

(51) Int. Cl. H01L 21/02; H01L 23/66

(52) U.S. Cl. CPC H01L 21/02529; H01L 23/66; H01L 21/02378; H01L 21/02584; H01L 21/02579; H01L 21/0243; H01L 29/66462

(57) ABSTRACT

The present disclosure provides a radio frequency device, a silicon carbide homoepitaxial substrate and a manufacturing method thereof. The manufacturing method of the silicon carbide homoepitaxial substrate includes: providing an N-type silicon carbide substrate, forming first grooves in the N-type silicon carbide substrate; forming a defect repair layer on inner walls of the first grooves and outside the first grooves, and forming second grooves in the defect repair layer corresponding to the first grooves; forming an unintentionally doped silicon carbide layer on the defect repair layer, where the second grooves are fully filled with the unintentionally doped silicon carbide layer.

### CROSS REFERENCE TO RELATED APPLICATIONS

This application claims priority to Chinese Patent Application No. 202111222935.0, filed on Oct. 20, 2021, the entire content of which is incorporated herein by reference.

### TECHNICAL FIELD

The present disclosure relates to the field of semiconductor, and more particular, to radio frequency devices, silicon carbide homoepitaxial substrates and manufacturing methods thereof.

### BACKGROUND

The third-generation semiconductors represented by group III nitrides have excellent properties such as wide band gap, high breakdown electric field, high saturation electron drift velocity, and strong polarization, especially high mobility transistors (HEMTs) with AlGaN/GaN heterostructure based on silicon-substrate or silicon-carbide-substrate have excellent characteristics such as fast switching speed, low on-resistance, small device size, high temperature resistance, and energy saving, which are expected to be widely used in the field of next-generation microwave radio frequency power devices.

At present, GaN-based microwave radio frequency electronic device generally have a structure of gallium nitride (GaN) epitaxially grown on silicon carbide (SiC) substrate, because of the excellent heat dissipation performance and radio frequency performance of silicon carbide (SiC) substrate. However, to improve radio frequency performance, a non-conductive SiC substrate is required, however commercially available SiC substrates are generally N-type conductive.

### SUMMARY

A first aspect of the present disclosure provides a method of manufacturing a silicon carbide homoepitaxial substrate, including: providing an N-type silicon carbide substrate, forming first grooves in the N-type silicon carbide substrate; forming a defect repair layer on inner walls of the first grooves and outside the first grooves, and forming second grooves in the defect repair layer corresponding to the first grooves; forming an unintentionally doped silicon carbide layer on the defect repair layer, where the second grooves are fully filled with the unintentionally doped silicon carbide layer.

A second aspect of the present disclosure provides a silicon carbide homoepitaxial substrate, including: an N-type silicon carbide substrate with first grooves; a defect repair layer on inner walls of the first grooves and outside the first grooves, provided with second grooves corresponding to the first grooves; an unintentionally doped silicon carbide layer on the defect repair layer, wherein the second grooves are fully filled with the unintentionally doped silicon carbide layer.

A third aspect of the present disclosure provides a radio frequency device, including: a silicon carbide homoepitaxial substrate, where the silicon carbide homoepitaxial substrate includes: an N-type silicon carbide substrate with first grooves; a defect repair layer on inner walls of the first grooves and outside the first grooves, provided with second grooves corresponding to the first grooves; an unintentionally doped silicon carbide layer on the defect repair layer, wherein the second grooves are fully filled with the unintentionally doped silicon carbide layer; and an epitaxial substrate on the silicon carbide homoepitaxial substrate.

### BRIEF DESCRIPTION OF DRAWINGS

FIG. 1 is a flowchart of a method of manufacturing a silicon carbide homoepitaxial substrate according to a first embodiment of the present disclosure;

FIG. 2 to FIG. 3 are schematic views illustrating intermediate structures corresponding to processes of FIG. 1;

FIG. 4 is a cross-sectional structure diagram of a silicon carbide homoepitaxial substrate according to a first embodiment of the present disclosure;

FIG. 5 is a cross-sectional structure diagram of a silicon carbide homoepitaxial substrate according to a second embodiment of the present disclosure;

FIG. 6 is a cross-sectional structure diagram of a silicon carbide homoepitaxial substrate according to a third embodiment of the present disclosure; and

FIG. 7 is a cross-sectional structural diagram of a silicon carbide homoepitaxial substrate according to a fourth embodiment of the present disclosure.

### DETAILED DESCRIPTION

In order to make the above-mentioned objects, features and advantages of the present disclosure more obvious and understandable, embodiments of the present disclosure will be described in detail below with reference to the accompanying drawings.

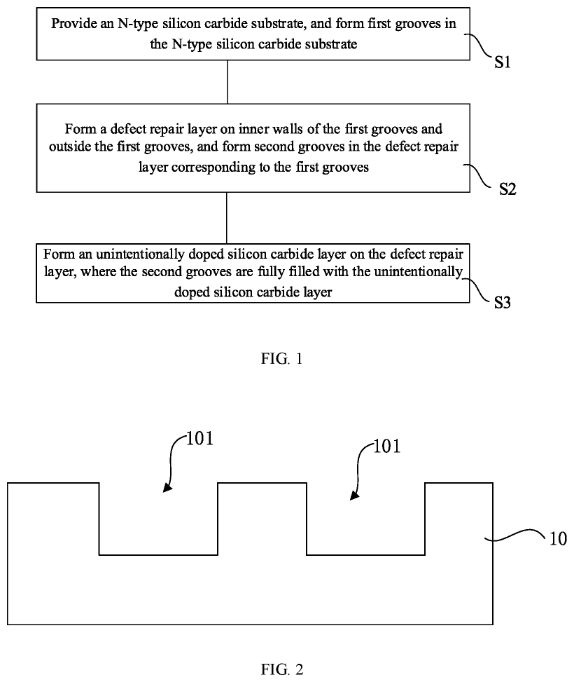

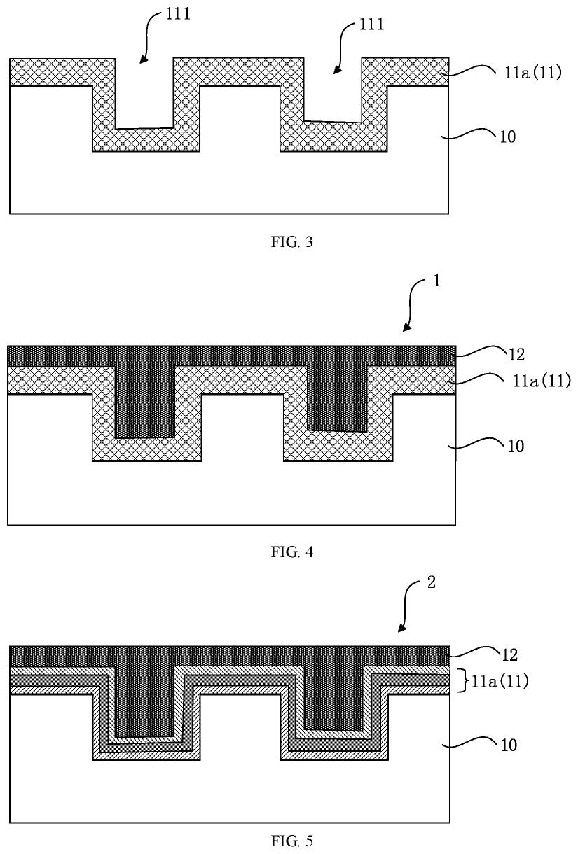

FIG. 1 is a flowchart of a method of manufacturing a silicon carbide homoepitaxial substrate according to a first embodiment of the present disclosure; and FIG. 2 to FIG. 3 are schematic views illustrating intermediate structures corresponding to processes of FIG. 1. FIG. 4 is a cross-sectional structure diagram of a silicon carbide homoepitaxial substrate according to a first embodiment of the present disclosure.

First of all, referring to step S1 in FIG. 1 and FIG. 2, an N-type silicon carbide substrate 10 is provided, and first grooves 101 are formed in the N-type silicon carbide substrate 10.

The N-type silicon carbide substrate 10 may have many defects therein. In addition, the N-type silicon carbide substrate 10 can be a silicon carbide substrate with a deflection angle, or can be a silicon carbide substrate without a deflection angle.

N-type doped ions in the N-type silicon carbide substrate 10 can include aluminum (Al) ions.

The first grooves 101 can be formed by dry etching, wet etching or laser trenching. In the dry etching or wet etching process, a patterned AlN layer can be configured as a mask, the N-type silicon carbide substrate 10 is etched to form first grooves 101. On a plane perpendicular to a thickness direction of the N-type silicon carbide substrate 10, the cross-section shape of each of the first grooves 101 can be a polygon, such as a triangle, a rectangle, a pentagon, a hexagon, or the like. Compared with a first groove 101 with a circular or elliptical shape, the first groove 101 with polygonal shape has more steps. In addition, a depth to width ratio of the first groove 101 can range from 1:1 to 1:3, and the present disclosure is not limited thereto.

With reference to step S2 in FIG. 1 and FIG. 3, a defect repair layer 11 is formed on inner walls of the first grooves 101 and outside the first grooves 101, and second grooves 111 are formed in the defect repair layer 11 corresponding to the first grooves 101.

In this embodiment, the defect repair layer 11 is a P-type silicon carbide layer 11a. Formation process of forming the P-type silicon carbide layer 11a can include: Atomic Layer Deposition (ALD), or Chemical Vapor Deposition (CVD), or molecular beam epitaxial (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof. P-type doped ions in the P-type silicon carbide layer 11a can be phosphorus (P) ions, and the phosphorus ions can be in-situ doped in the P-type silicon carbide layer 11a, or after the epitaxial growth of the silicon carbide layer is completed, the phosphorus ions can be doped in the P-type silicon carbide layer 11a by ion implantation.

In this embodiment, the P-type silicon carbide layer 11a is a single layer. In a thickness direction of the N-type silicon carbide substrate 10, the doping concentration of P-type ion in the P-type silicon carbide layer 11a can be uniform, or the P-type ion doping of the P-type silicon carbide layer 11a can be modulation doping or Delta doping.

Compared with growing the silicon carbide layer on a flat surface, the P-type silicon carbide layer 11a is easy to nucleate and grow at the steps of the N-type silicon carbide substrate 10, and the defects in the N-type silicon carbide substrate 10 can be repaired in an interface between the N-type silicon carbide substrate 10 and the P-type silicon carbide layer 11a. In other words, the P-type silicon carbide layer 11a can terminate defects in the N-type silicon carbide substrate 10.

In this embodiment, the defect repair layer 11 does not fully fill the first grooves 101.

After that, referring to step S3 in FIG. 1 and FIG. 4, an unintentionally doped silicon carbide layer 12 is formed on the defect repair layer 11, and the second grooves 111 are fully filled with the unintentionally doped silicon carbide layer 12.

The formation process of the unintentionally doped silicon carbide layer 12 can refer to the formation process of the defect repair layer 11. Compared with growing the silicon carbide layer on a flat surface, the unintentionally doped silicon carbide layer 12 is also easy to nucleate and grow at the steps of the defect repair layer 11. For example, the step of the defect repair layer 11 can refer to an L-shaped position in the defect repair layer 11.

Since the defects in the N-type silicon carbide substrate 10 are terminated in the defect repair layer 11, a quality of the unintentionally doped silicon carbide layer 12 can be improved. Furthermore, a conductivity of the unintentionally doped silicon carbide layer 12 is lower than a conductivity of the N-type silicon carbide substrate 10.

In this embodiment, an upper surface of the unintentionally doped silicon carbide layer 12 is flat.

Referring to FIG. 4, in this embodiment, the silicon carbide homoepitaxial substrate 1 includes: an N-type silicon carbide substrate 10, where the N-type silicon carbide substrate 10 has first grooves 101; a defect repair layer 11 on inner walls of the first grooves 101 and outside the first grooves 101, provided with second grooves 111 corresponding to the first grooves 101; and an unintentionally doped silicon carbide layer 12 on the defect repair layer 11, where the second grooves are fully filled with the unintentionally doped silicon carbide layer 12.

In this embodiment, the defect repair layer 11 is a P-type silicon carbide layer 11a. The holes in the P-type silicon carbide layer 11a can be compensated with electrons in the unintentionally doped silicon carbide layer 12 to form a depletion layer. The depletion layer can reduce a leakage current of the substrate and meet requirements of the HEMT (High Electron Mobility Transistor) device and the like for the leakage current of the substrate.

The experimental results show that, in the thickness direction of the N-type silicon carbide substrate 10, compared with the P-type silicon carbide layer 11a with a uniform doping concentration of P-type ions, if the doping concentration of the P-type ions in the P-type silicon carbide layer 11a is Delta doping, the depletion layer formed by the unintentionally doped silicon carbide layer 12 and P-type silicon carbide layer 11a is thicker, and the effect of reducing the leakage current of the substrate is better.

In other embodiments, in addition to the Delta doping, the doping concentration of P-type ions in the P-type silicon carbide layer 11a can also have other distributions.

In addition, there are fewer defects in the unintentionally doped silicon carbide layer 12, so that high quality GaN epitaxial material can be epitaxially grown thereon to form GaN devices, such as radio frequency devices.

FIG. 5 is a cross-sectional structure diagram of a silicon carbide homoepitaxial substrate according to a second embodiment of the present disclosure. Referring to FIG. 5, a difference between the silicon carbide homoepitaxial substrate 2 in the second embodiment and the silicon carbide homoepitaxial substrate 1 in the first embodiment is that: the P-type silicon carbide layer 11a includes multiple sub-layers, and in a thickness direction of the N-type silicon carbide substrate 10, a doping concentration of P-type ions in the P-type silicon carbide layer is Delta distribution. In other words, in the multiple sub-layers of P-type silicon carbide layer 11a, the doping concentrations of P-type ions in a top sub-layer and a bottom sub-layer of the P-type silicon carbide layer 11a have relatively small concentrations, and the doping concentration of P-type ions in one or more middle sub-layers of the P-type silicon carbide layer 11a has a higher concentration. For example, the doping concentration of P-type ions in the one or more middle sub-layers of the P-type silicon carbide layer 11a is greater than doping concentrations of P-type ions in the top sub-layer and the bottom sub-layer of the P-type silicon carbide layer 11a.

The beneficial effect of the doping concentration of P-type ions in the P-type silicon carbide layer 11a being a Delta distribution is that a thickness of the depletion layer formed between the P-type silicon carbide layer 11a and the unintentionally doped silicon carbide layer 12 can be further increased to reduce leakage current.

In addition to the above-mentioned difference, for other structures of the silicon carbide homoepitaxial substrate 2 of the second embodiment, reference can be made to the corresponding structures of the silicon carbide homoepitaxial substrate 1 of the first embodiment.

Correspondingly, the difference between the manufacturing method of the silicon carbide homoepitaxial substrate 2 in the second embodiment and the manufacturing method of the silicon carbide homoepitaxial substrate 1 in the first embodiment is that: at step S2, the P-type silicon carbide layer 11a includes multiple sub-layers, and in the thickness direction of the N-type silicon carbide substrate 10, the doping concentration of P-type ions in the P-type silicon carbide layer 11a is a Delta distribution. The doping concentration of P-type ions can be controlled by in-situ growth, or the doping concentrations of P-type ions in P-type silicon carbide layers located at different depths can be controlled by ion implantation.

In addition to the above-mentioned difference, other steps of the method of manufacturing the silicon carbide homoepitaxial substrate 2 in the second embodiment can refer to the corresponding steps in the method of manufacturing the silicon carbide homoepitaxial substrate 1 in the first embodiment.

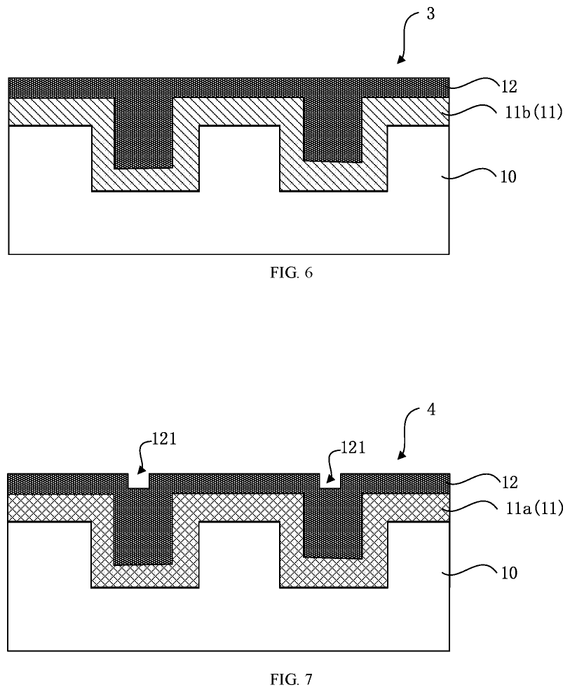

FIG. 6 is a cross-sectional structure diagram of a silicon carbide homoepitaxial substrate according to a third embodiment of the present disclosure. Referring to FIG. 6, a difference between the silicon carbide homoepitaxial substrate 3 of the third embodiment and the silicon carbide homoepitaxial substrate 1 of the first embodiment is that: the defect repair layer 11 is a mixture layer with gradual AlN:SiC ratio (may also be referred to as a mixture layer 11b). The mixture layer 11b can be used as a dense barrier layer to prevent N-type impurities in the N-type silicon carbide substrate 10 from diffusing upward to the unintentionally doped silicon carbide layer 12. In other words, the mixture layer 11b can reduce an electrical conductivity of the silicon carbide homoepitaxial substrate 3. This is because: the N-type silicon carbide substrate 10 has N-type element impurities, and the unintentionally doped silicon carbide layer 12 also has N-type element impurities, and the subsequent preparations of radio frequency device require that the conductivity of the substrate is as small as possible, and the mixture layer 11b can prevent the diffusion of N-type element impurities in the N-type silicon carbide substrate 10 to the unintentionally doped silicon carbide layer 12.

In an example, in the direction away from the N-type silicon carbide substrate 10, a proportion of SiC in the mixture layer 11b increases gradually, and a proportion of AlN decreases gradually. The beneficial effect is that: the unintentionally doped silicon carbide layer 12 can be epitaxially grown on a homogenous substrate, and a quality of the unintentionally doped silicon carbide layer 12 can be improved.

In other embodiments, the defect repair layer 11 can also be a superlattice structure layer with gradual AlN:SiC ratio. The superlattice structure layer generally leads to a deflection of defect direction in the defect repair layer 11, which further reduces a defect density in the defect repair layer 11.

In an example, in the superlattice structure layer with gradual AlN:SiC ratio, the farther away from the N-type silicon carbide substrate 10 is, the larger the proportion of SiC is, and the smaller the proportion of AlN is. The beneficial effect is that: the unintentionally doped silicon carbide layer 12 can be epitaxially grown on a homogenous substrate, and a quality of the unintentionally doped silicon carbide layer 12 can be improved.

In addition to the above-mentioned difference, for other structures of the silicon carbide homoepitaxial substrate 3 of the third embodiment, reference can be made to the corresponding structures of the silicon carbide homoepitaxial substrate 1 of the first embodiment.

Correspondingly, the difference between the method of manufacturing the silicon carbide homoepitaxial substrate 3 of the third embodiment and the method of manufacturing the silicon carbide homoepitaxial substrate 1 of the first embodiment is that: at step S2, the mixture layer 11b is formed on inner walls of the first grooves 101 and outside the first grooves 101. For the formation process of the mixture layer 11b, reference can be made to the formation process of the P-type silicon carbide layer 11a.

In addition to the above-mentioned difference, other steps of the method of manufacturing the silicon carbide homoepitaxial substrate 3 in the third embodiment can refer to the corresponding steps in the method of manufacturing the silicon carbide homoepitaxial substrate 1 in the first embodiment.

FIG. 7 is a cross-sectional structural diagram of a silicon carbide homoepitaxial substrate according to a fourth embodiment of the present disclosure. Referring to FIG. 7, a difference between the silicon carbide homoepitaxial substrate 4 of the fourth embodiment and the silicon carbide homoepitaxial substrate 1, silicon carbide homoepitaxial substrate 2 and silicon carbide homoepitaxial substrate 3 of the first, second and third embodiments is that: there are third grooves 121 on the unintentionally doped silicon carbide layer 12, and positions of the third grooves 121 correspond to positions of the second grooves 111 respectively.

The beneficial effect of providing the third grooves 121 is that: the GaN epitaxial material is easily nucleated and grown at steps of the unintentionally doped silicon carbide layer 12. The step of the unintentionally doped silicon carbide layer 12 can refer to an L-shaped position in the unintentionally doped silicon carbide layer 12.

In addition to the above-mentioned difference, for other structures of the silicon carbide homoepitaxial substrate 4 of the fourth embodiment, reference can be made to the corresponding structures of the silicon carbide homoepitaxial substrates 1, 2 and 3 of the first, second and third embodiments.

Correspondingly, the difference between the method of manufacturing the silicon carbide homoepitaxial substrate 4 of the fourth embodiment and the method of manufacturing the silicon carbide homoepitaxial substrate 1 of the first embodiment is that: at step S3, the unintentionally doped silicon carbide layer 12 with third grooves 121 is formed on the defect repair layer 11, and positions of the third grooves 121 correspond to the positions of the second grooves 111 respectively.

In addition to the above-mentioned difference, other steps of the method of manufacturing the silicon carbide homoepitaxial substrate 4 in the fourth embodiment can refer to the corresponding steps in the method of manufacturing the silicon carbide homoepitaxial substrates 1, 2 and 3 in the first, second and third embodiments.

The fifth embodiment of the present disclosure further provides a radio frequency device, including any of the above-mentioned silicon carbide homoepitaxial substrates 1, 2, 3, or 4 and an epitaxial structure on the silicon carbide homoepitaxial substrate.

Since high-quality GaN epitaxial materials can be epitaxially grown on the silicon carbide homoepitaxial substrates 1, 2, 3, or 4, the performance of the radio frequency device can be improved.

The beneficial effect of embodiments in the present disclosure is that the defect repair layer can be nucleated and grown at the L-shaped positions of the first grooves, so that the defects in the N-type silicon carbide substrate are repaired at an interface between the defect repair layer and the N-type silicon carbide substrate; the unintentionally doped silicon carbide layer can be nucleated and grown on the L-shaped positions of the second grooves. Since the defects of the N-type silicon carbide substrate are terminated in the defect repair layer, the quality of the unintentionally doped silicon carbide layer can be improved, and high-quality GaN epitaxial materials can be epitaxially grown on the silicon carbide homoepitaxial substrate.

In an example, the defect repair layer is a P-type silicon carbide layer. The holes in the P-type silicon carbide layer can be compensated with the electrons in the unintentionally doped silicon carbide layer to form a depletion layer, which meets the leakage current requirements for substrate of HEMT devices etc.

In an example, the defect repair layer is a mixture layer with gradual AlN:SiC ratio or a superlattice structure layer with gradual AlN:SiC ratio. The mixture layer or the superlattice structure layer can be used as a barrier layer for impurities and defects in N-type silicon carbide substrate to meet the low conductivity requirements for the substrate of radio frequency devices.

Although the present disclosure discloses the above contents, the present disclosure is not limited thereto. Any one of ordinary skill in the art can make various variants and modifications to the present disclosure without departing from the spirit and scope of the present disclosure. Therefore, the protection scope of the present disclosure should be set forth by the appended claims.

What is claimed is:

1. A silicon carbide homoepitaxial substrate, comprising:
an N-type silicon carbide substrate with first grooves;
a defect repair layer on inner walls of the first grooves and outside the first grooves, provided with second grooves corresponding to the first grooves; and
an unintentionally doped silicon carbide layer on the defect repair layer, wherein the second grooves are fully filled with the unintentionally doped silicon carbide layer.

2. The silicon carbide homoepitaxial substrate of claim 1, wherein the defect repair layer is a P-type silicon carbide layer.

3. The silicon carbide homoepitaxial substrate of claim 1, wherein a conductivity of the unintentionally doped silicon carbide layer is lower than a conductivity of the N-type silicon carbide substrate.

4. The silicon carbide homoepitaxial substrate of claim 2, wherein in a thickness direction of the N-type silicon carbide substrate, doping of P-type ions in the P-type silicon carbide layer comprises at least one of: uniform doping, modulation doping, or Delta doping.

5. The silicon carbide homoepitaxial substrate of claim 2, wherein the P-type silicon carbide layer comprises multiple sub-layers, and in a thickness direction of the N-type silicon carbide substrate, a doping concentration of P-type ions in the P-type silicon carbide layer is Delta distribution.

6. The silicon carbide homoepitaxial substrate of claim 5, wherein in the P-type silicon carbide layer, a doping concentration of P-type ions in one or more middle sub-layers of the P-type silicon carbide layer is greater than doping concentrations of P-type ions in a top sub-layer and a bottom sub-layer of the P-type silicon carbide layer.

7. The silicon carbide homoepitaxial substrate of claim 1, wherein the defect repair layer is a mixture layer with gradual AlN:SiC ratio or a superlattice structure layer with gradual AlN:SiC ratio.

8. The silicon carbide homoepitaxial substrate of claim 1, wherein an upper surface of the unintentionally doped silicon carbide layer is flat; or
the unintentionally doped silicon carbide layer has third grooves corresponding to the second grooves.

9. The silicon carbide homoepitaxial substrate of claim 1, wherein on a plane perpendicular to a thickness direction of the N-type silicon carbide substrate, a cross-section shape of each of the first grooves is polygonal.

10. A method of manufacturing silicon carbide homoepitaxial substrate, comprising:
providing an N-type silicon carbide substrate;
forming first grooves in the N-type silicon carbide substrate;
forming a defect repair layer on inner walls of the first grooves and outside the first grooves;
forming second grooves in the defect repair layer corresponding to the first grooves; and
forming an unintentionally doped silicon carbide layer on the defect repair layer, wherein the second grooves are fully filled with the unintentionally doped silicon carbide layer.

11. The method of claim 10, wherein the defect repair layer is a P-type silicon carbide layer.

12. The method of claim 10, wherein a conductivity of the unintentionally doped silicon carbide layer is lower than a conductivity of the N-type silicon carbide substrate.

13. The method of claim 11, wherein in a thickness direction of the N-type silicon carbide substrate, doping of P-type ions in the P-type silicon carbide layer comprises at least one of: uniform doping, modulation doping, or Delta doping.

14. The method of claim 11, wherein the P-type silicon carbide layer comprises multiple sub-layers, and in a thickness direction of the N-type silicon carbide substrate, a doping concentration of P-type ions in the P-type silicon carbide layer is Delta distribution.

15. The method of claim 14, wherein in the P-type silicon carbide layer, a doping concentration of P-type ions in one or more middle sub-layers of the P-type silicon carbide layer is greater than doping concentrations of P-type ions in a top sub-layer and a bottom sub-layer of the P-type silicon carbide layer.

16. The method of claim 10, wherein the defect repair layer is a mixture layer with gradual AlN:SiC ratio or a superlattice structure layer with gradual AlN:SiC ratio.

17. The method of claim 16, wherein
in response to determining that the defect repair layer is the mixture layer with gradual AlN:SiC ratio, in a direction away from the N-type silicon carbide substrate, a proportion of SiC in the mixture layer increases gradually; and
in response to determining that the defect repair layer is the superlattice structure layer with gradual AlN:SiC ratio, in the direction away from the N-type silicon carbide substrate, a proportion of SiC in the superlattice structure layer increases gradually.

18. The method of claim 10, wherein
an upper surface of the unintentionally doped silicon carbide layer is flat; or
the unintentionally doped silicon carbide layer has third grooves corresponding to the second grooves.

19. The method of claim 10, wherein on a plane perpendicular to a thickness direction of the N-type silicon carbide substrate, a cross-section shape of each of the first grooves is polygonal.

20. A radio frequency device, comprising:
a silicon carbide homoepitaxial substrate,
wherein the silicon carbide homoepitaxial substrate comprises:
an N-type silicon carbide substrate with first grooves;
a defect repair layer on inner walls of the first grooves and outside the first grooves, provided with second grooves corresponding to the first grooves; and
an unintentionally doped silicon carbide layer on the defect repair layer, wherein the second grooves are fully filled with the unintentionally doped silicon carbide layer; and
an epitaxial substrate on the silicon carbide homoepitaxial substrate.
